(19) United States
(12) Patent Application Publication
(10) Pub. No.: US 2004/0003896 A1
(43) Pub. Date: Jan. 8, 2004

(54) Controller for plasma processing apparatus performing good etching process

(75) Inventor: Keiichi Sugahara, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/337,343

(22) Filed: Jan. 7, 2003

(30) Foreign Application Priority Data
Jul. 2, 2002 (JP) 2002-192995(P)

(51) Int. Cl. H01L 21/306

(52) U.S. Cl. 156/345.28

(57) ABSTRACT

A controller for a dry-etching apparatus includes a memory storing a database in which a product number of a wafer after processing, data relating to a pattern dimension as well as an impedance measured during wafer processing and a setting parameter are associated, and a CPU controlling the dry-etching apparatus. The CPU executes the processes of reading from the database an impedance corresponding to the product number of the wafer to be processed, comparing the read impedance with an impedance monitor value measured relative to the wafer to be processed, and modifying a parameter that has been set, using the setting parameter stored in the database, based on the comparison result.

### BACKGROUND OF THE INVENTION

1. Field of the Invention

The present invention relates to a technique for manufacturing a semiconductor wafer, and more particularly, to a plasma processing technique using, for example, a dry-etching apparatus, a plasma CVD (Chemical Vapor Deposition) apparatus, a sputtering apparatus, and the like.

2. Description of the Background Art

Recently, plasma processing has widely been used for substance surface treatment, including microfabrication by dry-etching, thin-film formation, surface reform and the like. Plasma processing is an essential technique for manufacturing a VLSI (a very large scale integrated circuit) particularly in a field of manufacturing a semiconductor.

As a semiconductor integrated circuit is made smaller, recently, it is necessary to generate high-density plasma under high vacuum. Accordingly, an inductively coupled plasma generator that generates plasma by an action of an inductive field formed by a high-frequency current flowing in a coil on a space under reduced pressure has attracted attention. In addition, a plasma processing apparatus using the same also has attracted attention.

In the dry-etching apparatus, when plasma is generated in high vacuum, ions in an ion sheath formed on the surface of a substrate are less likely to collide with ions or other neutral gas particles. Therefore, the ions will be uniformly directed toward the substrate, and etching anisotropy will be enhanced. Thus, processing implementing high aspect ratio will be possible. In addition, for plasma CVD, when plasma is generated in high vacuum, sputtering with ions will effectively embed fine patterns and realize planarization, and processing implementing high aspect ratio will be possible. In such a plasma processing apparatus, yield in a manufacturing process of a semiconductor wafer is improved by real-time monitoring of fluctuation in plasma processing.

Japanese Patent Laying-Open No. 10-125660 discloses an apparatus monitoring fluctuation of plasma property processing in real time. The apparatus disclosed herein includes a signal sampling circuit measuring an electric signal reflecting a plasma state; a model formula storage circuit storing a model formula associating a value for the electric signal with the plasma processing property; an arithmetic circuit substituting the value for the electric signal measured by the signal sampling circuit into the model formula read from the model formula storage circuit, and calculating an estimate value for the plasma processing property; and a diagnostic circuit diagnosing a plasma state based on the estimate value for the plasma processing property.

With this apparatus, a plasma state can be estimated by substituting the electric signal measured in real-time into the model formula. Therefore, when the plasma processing property may change, an operator can know it immediately, and production of a large amount of defective wafers can be avoided before it happens. In addition, parameters of electric signals, such as current, voltage, phase and the like are not individually monitored in the model formula, but a balance of the plurality of parameters can be associated with the plasma processing property and the like for collective monitoring. Therefore, it is easier to diagnose a cause of an abnormal condition of the apparatus. Consequently, it is possible to monitor, in real-time, fluctuation and change over time of a plasma processing property, as well as to improve manufacturing yield and productivity.

Japanese Patent Laying-Open No. 2001-7089 discloses a method of controlling a plasma state generated during plasma processing. The method disclosed herein performs plasma processing, in which high-frequency power is supplied to a coil from a high-frequency power supply via an impedance matching device, to produce a magnetic field in a chamber, and a gas introduced in the chamber is turned to plasma for processing. The method includes the steps of detecting a change of the plasma state during plasma processing, and controlling any of or all of an amount of high-frequency power output from the high-frequency power supply, an amount of gas supply, and pressure in the chamber, based on a detected result.

According to the method, during plasma discharge in which plasma processing is being performed, a waveform of current and voltage will undergo distortion in a variety of manners. Distortion/fluctuation of the waveforms corresponds to a change of the plasma state, and a different form will be represented in accordance with process conditions. Though it has conventionally been unclear how the plasma state changes, it has been found that change of harmonic components, measured up to the fifth order respectively for voltage, current, phase difference, impedance and power, correlates with a plasma processing result. Thus, the plasma state can properly be controlled by detecting the change thereof during plasma processing, and controlling any of or all of the amount of high-frequency power output from the high-frequency power supply, the amount of gas supply, and the pressure in the chamber, based on the detected result.

In an apparatus disclosed in Japanese Patent Laying-Open No. 10-125660, at least one of voltage, current, phase, impedance and self-bias current between a matching device and an electrode that applies plasma-generating high-frequency power in a signal sampling circuit is measured in real-time. The measured value is then substituted into a model formula for estimating a plasma state. When etching uniformity, which is a plasma processing property, may vary, an operation result from the model formula will vary. Accordingly, an operator can know a possibility of an occurrence of an abnormal condition. The apparatus, however, simply notifies the operator of a diagnostic result of the plasma state. Therefore, the operator can only know the possibility of the occurrence of the abnormal condition from the plasma processing result. The operator has to find out a cause in response to the alarm, and to adjust a control parameter.

A method disclosed in Japanese Patent Laying-Open No. 2001-7089, in detecting step, detects a change in the plasma state by measuring voltage, current, phase difference and impedance between a coil and an impedance matching device, that correlates, for example, with a plasma processing result. Based on the measurement result, an amount of high-frequency power output from a high-frequency power supply, an amount of gas supply, pressure in a chamber and the like are controlled. Here, however, a target to be controlled is obvious, while an amount thereof to be controlled corresponding to the measurement result is unclear. Consequently, it is unclear how actual control is performed.

### SUMMARY OF THE INVENTION

An object of the present invention is to provide a controller controlling a plasma processing apparatus capable of performing good plasma processing in a manufacturing process of a semiconductor wafer.

Another object of the present invention is to provide a controller controlling a plasma processing apparatus, in which high-frequency power is supplied from a high-frequency power supply via an impedance matching device to a coil, to produce a magnetic field in a chamber, and a gas introduced in the chamber is turned to plasma for wafer processing.

Yet another object of the present invention is to provide a controller controlling a plasma processing apparatus, based on an impedance measured between a coil and an impedance matching device.

Yet another object of the present invention is to provide a controller controlling a plasma processing apparatus, based on data stored in advance and an impedance measured between a coil and an impedance matching device.

A controller according to the present invention controls a plasma processing apparatus, in which high-frequency power is supplied from a high-frequency power supply via an impedance matching device to a coil, to produce a magnetic field in a chamber, and a gas introduced in the chamber is turned to plasma for wafer processing. A process condition in the plasma processing apparatus is determined by a plurality of setting parameters. The controller includes measurement instrument arranged between the coil and the impedance matching device to measure an impedance; a storage circuit storing data relating to a geometry of the wafer after processing, information on the wafer after processing as well as impedance measured during processing of the wafer after processing and the setting parameter that has been set, in association with one another; and a control circuit controlling the plasma processing apparatus. The control circuit includes a read circuit reading from the storage circuit, an impedance corresponding to a wafer to be processed, based on the wafer to be processed and information; a comparison circuit comparing the impedance read by the read circuit with the impedance measured by the measurement instrument relative to the wafer to be processed; and a modifying circuit modifying the setting parameter for processing the wafer to be processed based on the setting parameter stored in the storage circuit, using a comparison result from the comparison circuit.

The storage circuit stores database, in which data such as a pattern dimension relating to the geometry of the wafer after processing, information on the wafer after processing such as a type, as well as the impedance measured during processing of the wafer after processing and the setting parameter that has been set are associated. In a state where such a database is stored, the wafer to be processed is loaded to the plasma processing apparatus, etching process starts, and measurement instrument measures the impedance. In accordance with the comparison result based on the measured impedance and the impedance stored corresponding to the wafer to be processed, the setting parameter is modified by the modifying circuit. Here, the setting parameter stored in the storage circuit is used. Accordingly, a state of plasma fluctuated by a variety of factors can be monitored by observing the impedance. If the measured impedance does not match the stored impedance, for example, the setting parameter will be modified by the modifying circuit. When the setting parameter is modified and the impedances match, a desired etching process will be performed. Consequently, a controller for a plasma processing apparatus capable of performing good plasma process in a manufacturing process of a semiconductor wafer can be provided.

Preferably, the modifying circuit includes a circuit modifying the setting parameter for processing the wafer to be processed, based on the setting parameter corresponding to the wafer to be processed, when the comparison result indicates unmatch of the impedances.

The wafer to be processed is loaded to the plasma processing apparatus, plasma process starts, and the measurement instrument measures the impedance. If it is determined that the measured impedance does not match the impedance stored corresponding to the wafer to be processed, the setting parameter is modified by the modifying circuit. Accordingly, it is possible to monitor a state of plasma fluctuated by a variety of factors, by observing match/unmatch of the measured impedance with the stored impedance.

More preferably, the controller further includes a correction circuit correcting the impedance and the setting parameter stored in the storage circuit, when the comparison result indicating unmatch of the impedances is shown a predetermined times.

When the comparison result indicating that the measured impedance does not match the stored impedance is shown a predetermined times even if the setting parameter has been modified by the modifying circuit, the database is corrected. The correction is directed to the impedance and the setting parameter stored in the storage circuit. Therefore, the database is properly corrected, and the setting parameter is modified by the modifying circuit, based on the stored setting parameter. Thus, the impedances will match, and a desired etching process is performed.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a configuration of a dry-etching apparatus including a controller according to an embodiment of the present invention.

FIG. 2 shows a first database stored in a memory of the controller according to the embodiment of the present invention.

FIG. 3 shows a second database stored in the memory of the controller according to the embodiment of the present invention.

FIG. 4 is a flowchart showing a control procedure of a database creation process performed in the controller according to the embodiment of the present invention.

FIGS. 5A and 5B are flowcharts showing a control procedure of a wafer etching process performed in the controller according to the embodiment of the present invention.

FIG. 6 is a first diagram showing an impedance measured in an etching process in the controller according to the embodiment of the present invention.

FIG. 7 is a second diagram showing an impedance measured in the etching process in the controller according to the embodiment of the present invention.

### DESCRIPTION OF THE PREFERRED EMBODIMENTS

In the following, embodiments of the present invention will be described in detail with reference to the figures. It is noted that the same reference characters refer to the same or corresponding components in the figures.

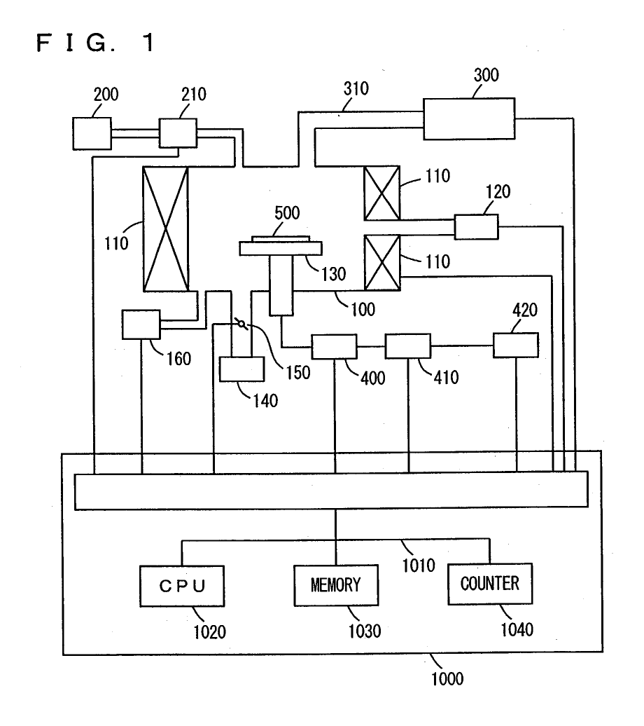

Referring to FIG. 1, a configuration of a dry-etching apparatus including a controller 1000 according to the present embodiment will be described. As shown in FIG. 1, the dry-etching apparatus includes an etching chamber 100, which is a pressure vessel, a coil 110 for producing a magnetic field, provided in etching chamber 100, and an etching end-point detector 120.

Etching chamber 100 includes a bias electrode 130 setting a wafer 500, a gas vent portion 140 connected via a pressure control valve 150, a pressure gauge 160 measuring a pressure inside etching chamber 100, a gas supply portion 200 connected via a mass flowmeter 210, and a plasma-generating high-frequency power supply 300 connected via a waveguide 310. Bias electrode 130 is connected to a bias-producing high-frequency power supply 420 via a plasma impedance monitor 400 and a matching box 410. Each of these components is connected to controller 1000.

A process gas is supplied from gas supply portion 200 to etching chamber 100, with a flow rate controlled by mass flow controller 210. The pressure in etching chamber 100 is detected by pressure gauge 160, and controlled by pressure control valve 150 preceding gas vent portion 140. High-frequency power is generated by plasma-generating high-frequency power supply 300 in order to turn the process gas in etching chamber 100 to plasma, which is supplied to etching chamber 100 through waveguide 310. Here, in order to increase plasma density in etching chamber 100, the magnetic field is applied by coil 110 for producing magnetic field.

Using plasma thus created, microfabrication such as interconnection on the wafer, holes and the like is performed. Meanwhile, in order to control anisotropy of an etching shape with ions in plasma, bias-producing high-frequency power supply 420 supplying high-frequency power is connected to bias electrode 130 also serving as a wafer stage via matching box 410 for matching impedance to that of plasma. Here, in order to determine a just etch time indicating the etching end-point, an etching endpoint detector 120 such as a photomultiplier is provided.

Controller 1000 includes an interface 1000 with equipment provided in each portion of the dry-etching apparatus, a bus 1010 connected to interface 1000, a CPU (Central Processing Unit) 1020 connected to bus 1010 and controlling the dry-etching apparatus via controller 1000, a program executed in CPU 1020, a memory 1030 storing the execution result of the program and the database, and a counter 1040 counting with respect to a preset value. Plasma impedance monitor 400 is inserted between bias electrode 130 and matching box 410 to measure the impedance.

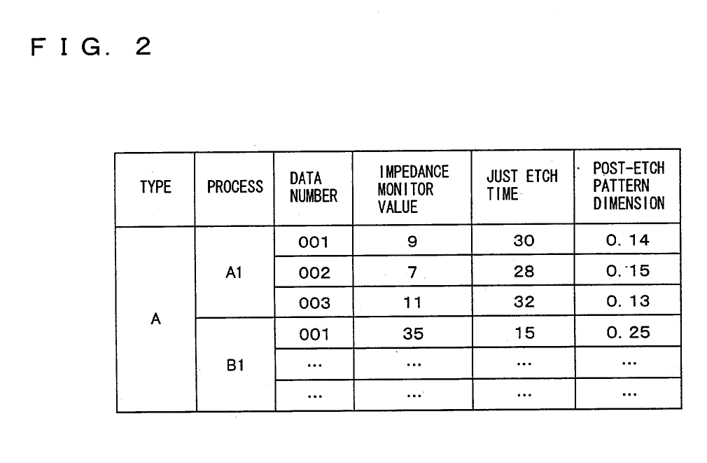

Referring to FIG. 2, a first database stored in memory 1030 of controller 1000 according to the present embodiment will be described. As shown in FIG. 2, the first database stores an impedance monitor value, the just etch time and the post-etch pattern dimension, for each of type, process and data number of wafer 500. As shown in FIG. 2, the first database stores the impedance monitor value measured by plasma impedance monitor 400, the just etch time detected by etching end-point detector 120 and the post-etch pattern dimension measured by a dimension measurement instrument such as a length measuring SEM (Scanning Electron Microscope), for each of type, process and data number of wafer 500.

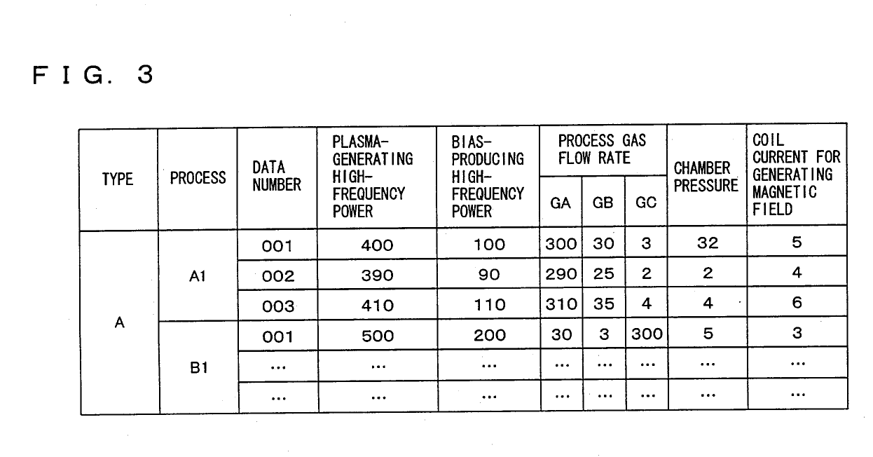

Referring to FIG. 3, a second database stored in memory 1030 of controller 1000 according to the present embodiment will be described. As shown in FIG. 3, as in the first database shown in FIG. 2, the second database stores the plasma-generating high-frequency power, the bias-producing high-frequency power, the flow rate of the process gas, the chamber pressure, and the coil current for producing a magnetic field, for each of type, process and data number of wafer 500. The plasma-generating high-frequency power represents power supplied to plasma-generating high-frequency power supply 300, and the bias-producing high-frequency power represents power supplied to bias-producing high-frequency power supply 420. The flow rate of the process gas is measured by mass flowmeter 210. The chamber pressure is measured by pressure gauge 160. The coil current for producing the magnetic field shows a value for current supplied to coil 110 for producing the magnetic field.

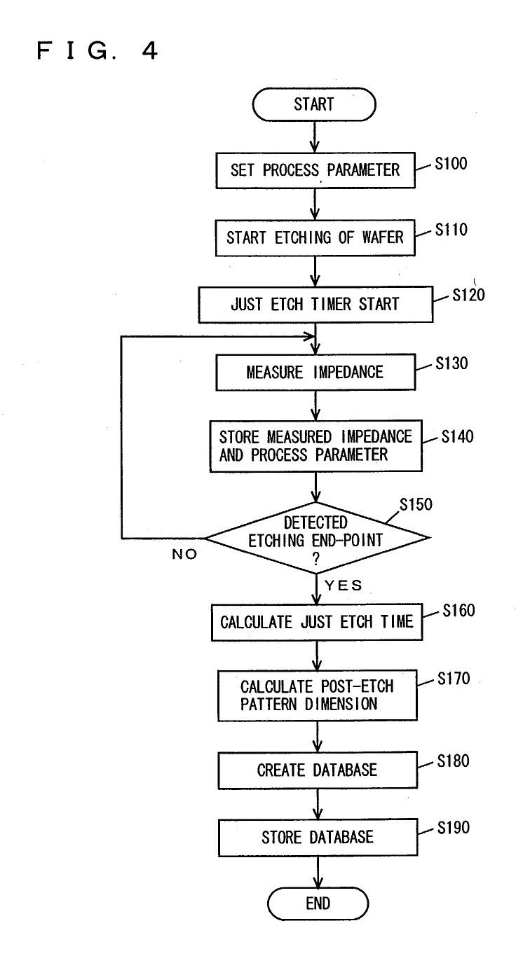

Referring to FIG. 4, the program executed in CPU 1020 of controller 1000 according to the present embodiment has a control configuration as follows, with regard to creation and process of the database.

At step 100 (hereinafter, a step is abbreviated as “S”), CPU 1020 sets a process parameter. The process parameter is set based on an empirical value or the like by an operator. At S110, CPU 1020 starts etching of the wafer. At S120, CPU 1020 starts a timer embedded therein to initiate a just etch timer.

At S130, CPU 1020 measures an impedance using plasma impedance monitor 400. At S140, CPU 1020 stores the measured impedance and the process parameter in memory 1030. At S150, CPU 1020 determines whether the etching end-point has been detected or not. The determination is performed based on a signal received by CPU 1020 from etching end-point detector 120. If the etching end-point is detected (YES at S150), the process will proceed to S160. If it is not detected (NO at S150), the process will return to S130.

At S160, CPU 1020 calculates a just etch time based on the value of the just etch timer embedded in CPU 1020. At S170, CPU 1020 calculates a post-etch pattern dimension. This process is performed by inputting a result obtained by measuring, for example, the post-etch pattern dimension using the length measuring SEM into an input apparatus (not shown) connected to controller 1000.

At S180, CPU 1020 creates the first database (FIG. 2) and the second database (FIG. 3). At S190, CPU 1020 stores the database created at S180 in memory 1030.

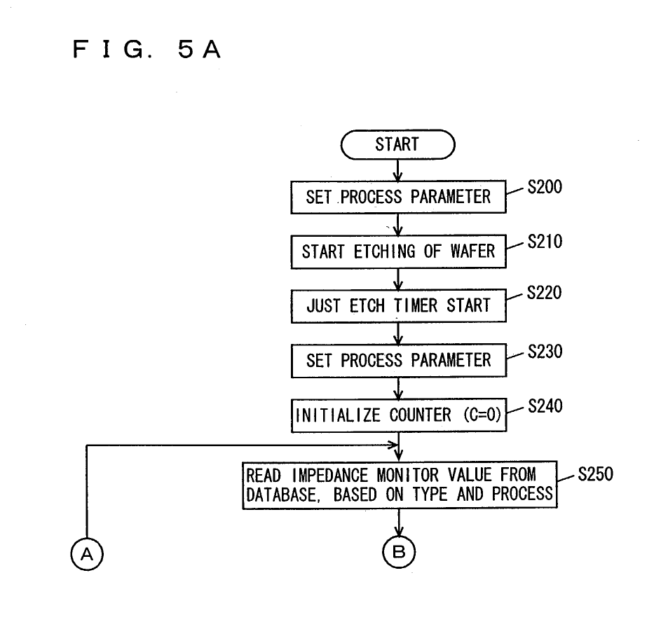

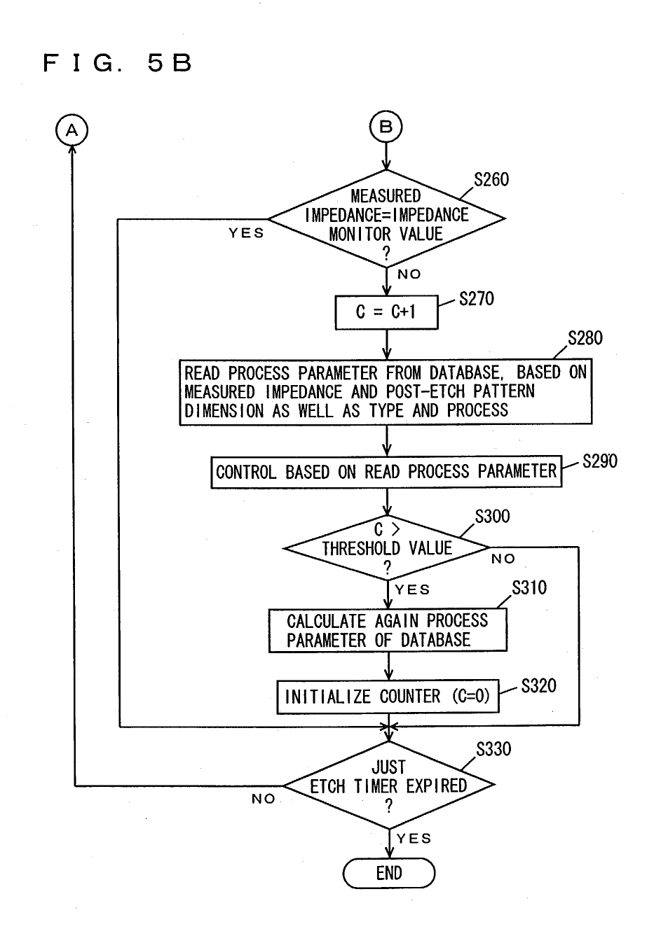

Referring to FIGS. 5A and 5B, the program executed in CPU 1020 of controller 1000 according to the present embodiment has a control configuration as follows, with regard to wafer etching process.

At S200, CPU 1020 sets a process parameter. At S210, CPU 1020 starts etching the wafer. At S220, CPU 1020 starts the just etch timer embedded therein. Here, based on the type and the like of wafer 500, the just etch time stored in the first database (FIG. 2) is set.

At S230, CPU 1020 sets the process parameter. At S240, CPU 1020 initializes counter 1040 (C=1).

At S250, CPU 1020 reads an impedance monitor value from the first database (FIG. 2), based on the type and the process.

At S260, CPU 1020 measures an impedance with plasma impedance monitor 400, and determines whether or not the measured impedance matches the impedance monitor value read from memory 1030. If the measured impedance matches the impedance monitor value (YES at S260), the process will proceed to S330. If not (NO at S160), the process will proceed to S270.

At S270, CPU 1020 increments the counter value by 1. At S280, CPU 1020 reads the process parameter from the second database (FIG. 3), based on the measured impedance, the post-etch pattern dimension, the type and the process. At S290, CPU 1020 controls the dry-etching apparatus based on the read process parameter.

At S300, CPU 1020 determines whether or not the counter value C is larger than a predetermined threshold value. If the counter value C is larger than the predetermined threshold value (YES at S300), the process will proceed to S310. If not (NO at S300), the process will proceed to S330.

At S310, CPU 1020 calculates again the process parameter of the second database (FIG. 3). At S320, CPU 1020 initializes the counter (C=0). At S330, CPU 1020 determines whether the just etch timer has expired or not. If the just etch timer has expired (YES at S330), the process ends. If not (NO at S330), the process will return to S250.

An operation of the dry-etching apparatus according to the present embodiment, based on the above-described configuration and the flowchart, will be described.

(Database Creating Operation)

When the operator sets the process parameter (S100) and predetermined conditions are satisfied, wafer etching starts (S110). The just etch timer starts (S120), and an impedance is measured by plasma impedance monitor 400 (S130). The measured impedance and the process parameter are stored in memory 1030 (S140). The impedance is measured (S130), and the measured impedance and the process parameter are repetitively stored in memory 1030 (S140) until etching end-point detector 120 detects the etching end-point (YES at S150).

When etching end-point detector 120 detects the etching end-point (YES at S150), the just etch time is calculated (S160). Then, the post-etch pattern dimension is measured using the length measuring SEM or the like (S170). The first database shown in FIG. 2 and the second database shown in FIG. 3 are created (S180), and the created databases are stored in memory 1030 (S190).

As described above, the first database (FIG. 2) and the second database (FIG. 3) are stored in memory 1030.

(Etching Operation)

When the databases (FIGS. 2 and 3) are stored in memory 1030 based on the above-described database creating operation, next wafer 500 to be processed is set in the dry-etching apparatus. The process parameter is set by the operator (S200), and wafer etching starts (S210). The just etch timer starts (S220), and the process parameter is set (S230). The counter is initialized (S240), and the impedance monitor value is read from the first database (FIG. 2) based on the type and the process of wafer 500 set in the dry-etching apparatus (S250). When the impedance measured by plasma impedance monitor 400 matches the read impedance monitor value (YES at S260), it is repetitively determined whether or not the measured impedance matches the impedance monitor value until the just etch timer expires (YES at S330).

If the impedance measured by plasma impedance monitor 400 does not match the read impedance monitor value (NO at S260), the counter is incremented by 1 (S270). The process parameter is read from the second database (FIG. 3), based on the measured impedance, the post-etch pattern dimension, the type and the process (S280). The dry-etching apparatus is controlled based on the read process parameter (S290). When the counter value is larger than the predetermined threshold value (YES at S300), the process parameter of the second database (FIG. 3) is calculated again (S310). Thereafter, the counter is initialized (S320), and the processes from S260 to S320 are repetitively performed again, until the just etch timer expires (NO at S330). Here, if the counter value C is not larger than the predetermined threshold value (NO at S300), the process parameter of the second database (FIG. 3) is not calculated again.

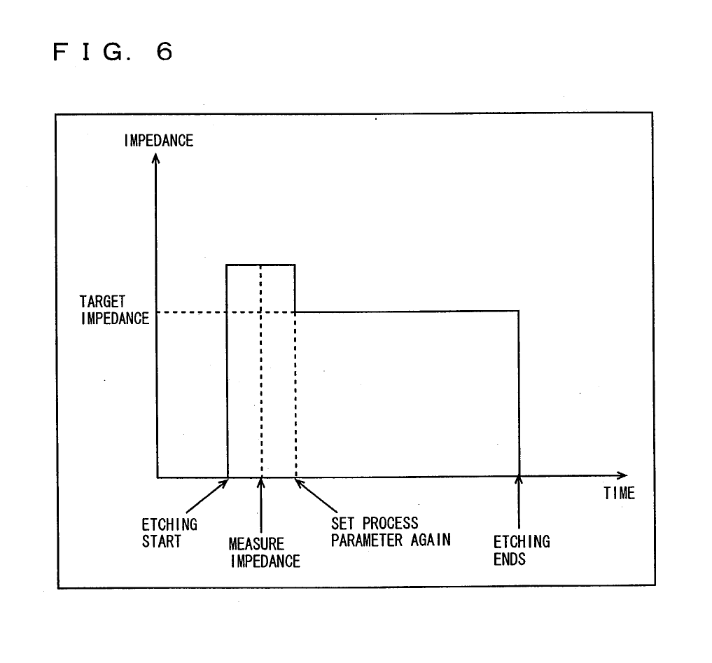

Referring to FIG. 6, change of the impedance in the dry-etching apparatus according to the present embodiment will be described. As shown in FIG. 6, when etching starts (S210), the impedance measured by plasma impedance monitor 400 is compared with the impedance monitor value read from memory 1030 (S260). When the measured impedance does not match the impedance monitor value (NO at S260), the process parameter is set again (S280, S290). By setting again the process parameter, the impedance attains the impedance monitor value stored in the first database (FIG. 2), the just etch timer expires (YES at S330), and etching ends.

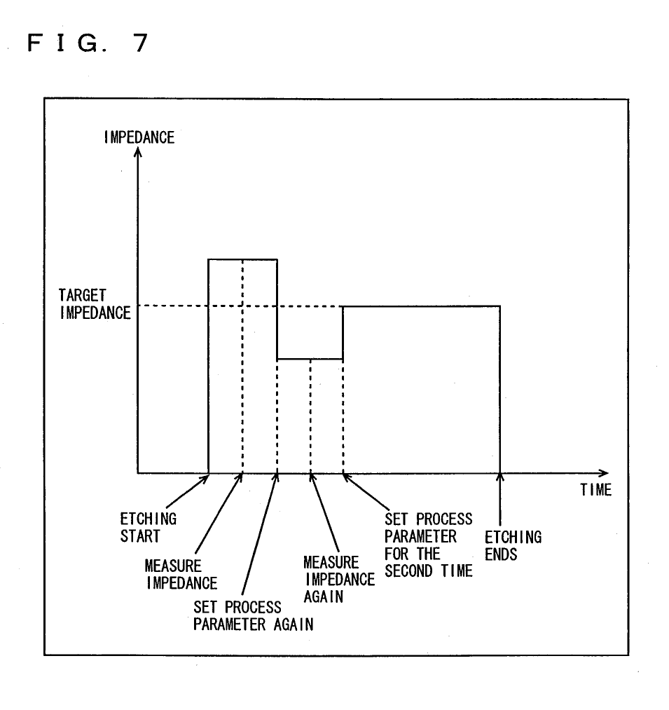

Referring to FIG. 7, an example, in which the process parameter is set for the second time, will be described. Etching starts (S210), and the impedance is measured. If the measured impedance does not match the read impedance monitor value (NO at S260), the process parameter is set again. When the process parameter is set again, the counter value is set to 1, and the impedance measured again does not match the impedance monitor value (NO at S260), then the counter is set to 2 (S270). In this state, the process parameter is set for the second time (S280, S290). When a target impedance, that is, the measured impedance, matches the impedance monitor value, the just etch timer expires (YES at S330) and etching ends.

As described above, according to a controller for a dry-etching apparatus according to the present embodiment, a database, in which a dry-etching pattern dimension, information such as a wafer type, as well as an impedance measured during wafer processing and a setting parameter that has been set are associated, is stored in a memory. In a state in which such a database is stored, a wafer to be processed is loaded to the dry-etching apparatus, and etching process starts. When the impedance is measured by a plasma impedance monitor. The measured impedance does not match an impedance monitor value stored in the memory corresponding to the wafer to be processed, the process parameter is read from the memory by a CPU. Control is performed based on that process parameter. Thus, plasma state fluctuated by a variety of factors can be monitored by observing the impedance. If the measured impedance does not match the stored monitor impedance value, the setting parameter is modified. When the setting parameter is modified and the impedances match, a desired etching process will be performed. Consequently, the controller for the dry-etching apparatus capable of performing good etching process in a manufacturing process of a semiconductor wafer can be provided.

The present invention relates to the plasma processing technique, for example, the above-mentioned dry-etching apparatus, and the present invention is not limited to the dry-etching technique.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A controller for a plasma processing apparatus in which high-frequency power is supplied from a high-frequency power supply via an impedance matching device to a coil to produce a magnetic field in a chamber, and a gas introduced in said chamber is turned to plasma for processing a wafer, a process condition in said plasma processing apparatus is determined by a plurality of setting parameters, said controller comprising:
measurement means for measuring an impedance, arranged between said coil and said impedance matching device;
storage means for storing data relating to a geometry of the wafer after processing, information on the wafer after said processing as well as impedance measured during processing of the wafer after said processing and a setting parameter that has been set, in association with one another; and
control means for controlling said plasma processing apparatus; wherein
said control means includes
read means for reading the impedance corresponding to a wafer to be processed from said storage means, based on said wafer to be processed and said information,
comparison means for comparing the impedance read by said read means with the impedance measured relative to said wafer to be processed by said measurement means, and
modifying means for modifying the setting parameter for processing said wafer to be processed based on said setting parameter stored in said storage means using a comparison result by said comparison means.

2. The controller for the plasma processing apparatus according to claim 1, wherein
said modifying means includes means for modifying the setting parameter for processing said wafer to be processed based on the setting parameter corresponding to said wafer to be processed, when said comparison result indicates unmatch of the impedances.

3. The controller for the plasma processing apparatus according to claim 1, further comprising correction means for correcting the impedance and the setting parameter stored in said storage means, when the comparison result indicating unmatch of the impedances is shown a predetermined times.

4. The controller for the plasma processing apparatus according to claim 1, wherein
the data stored in said storage means includes data based on a pattern dimension of said wafer.

5. The controller for the plasma processing apparatus according to claim 1, wherein
the information stored in said storage means includes information based on a type of said wafer.

6. The controller for the plasma processing apparatus according to claim 1, wherein
the setting parameter stored in said storage means includes at least one of a parameter relating to power supplied to said high-frequency power supply, a parameter relating to flow rate of said gas, a parameter relating current of said coil, and a parameter relating to pressure in said chamber.
